(19) United States
(12) Patent Application Publication
(10) Pub. No.: US 2025/0287500 A1
(43) Pub. Date: Sep. 11, 2025

(54) Electrically Conducting Structure for Flexible Circuit Board

(71) Applicant: Dongguan Kangxiang Electronic Co., Ltd, Guangdong Province (CN)

(72) Inventors: MING LUO, Dongguan (CN); YUNG- CHANG LIN, Dongguan (CN); YU-HUNG LIN, Dongguan (CN); HUNG-TIEN CHANG, Dongguan (CN); HSUAN HO CHUNG, Dongguan (CN)

(73) Assignee: Dongguan Kangxiang Electronic Co., Ltd, Guangdong Province (CN)

(21) Appl. No.: 19/007,485

(22) Filed: Jan. 1, 2025

(30) Foreign Application Priority Data
Mar. 5, 2024 (TW) TW113108014

(51) Int. Cl. H05K 1/11; H05K 1/02

(52) U.S. Cl. CPC H05K 1/11; H05K 1/0277; H05K 2201/09036

(57) ABSTRACT

An electrically conducting structure for a flexible circuit board, comprising a flexible substrate, a circuit layer, a soldering structure and an electrically connecting structure. The flexible substrate includes a first surface, a second surface, a lateral surface and a plurality of grooves. The first surface is opposite to the second surface, and the lateral surface connects the first surface and the second surface. The grooves are formed on the lateral surface and connect the first surface and the second surface. The circuit layer is formed on the first surface and includes an electrically conducting structure located near the lateral surface. The soldering structure is formed on the second surface. The electrically connecting structure extending form the first surface to the second surface connects the electrically conducting structure and the soldering structure.

### BACKGROUND OF THE INVENTION

### Field of the Invention

The present invention relates to the field of circuit board structure, more particularly, to a flexible substrate circuit board having electrical conduction structure.

### Description of the Related Art

Thinness is the current design trend of electronic product, therefore, multiple electronic modules of the electronic device have to be installed in a rather limited space. In this way, flexible circuit board or wire connection has become an essential choice to connect electronic modules. Currently, in most case, a circuit layer of the flexible circuit board is arranged on the surface of one side, which cannot be used in a structure that a circuit layer and a soldering structure are arranged on two different sides. Therefore, how to form the circuit layer and the soldering structure on two different sides of a flexible substrate to build electrical conduction becomes currently an important development direction of flexible circuit boards.

### BRIEF SUMMARY OF THE INVENTION

The primary objective of this invention is to provide an electrically conducting structure for flexible circuit board to provide a solution to the issue of connecting the circuits on two different sides of the flexible circuit board.

In one embodiment of the present invention, an electrically conducting structure for a flexible circuit board includes a flexible substrate, a circuit layer, at least a soldering structure and an electrically connecting structure. The flexible substrate includes a first surface, a second surface, a lateral surface and a plurality of grooves. The first surface is opposite to the second surface, and the lateral surface connects the first surface and the second surface. The grooves are formed on the lateral surface and connect the first surface and the second surface. The circuit layer is formed on the first surface and includes at least a conductive structure located near the lateral surface. The soldering structure is formed on the second surface. The electrically connecting structure extends form the first surface to the second surface and connects the conductive structure and the soldering structure.

In another embodiment of the present invention, the electrically connecting structure includes at least one conductive layer, and the conductive layer is formed on the wall of the groove and connects the conductive structure and the soldering structure.

In another embodiment of the present invention, the flexible substrate includes at least a thru hole, the thru hole goes thru the flexible substrate and connects the first surface and the second surface, and the electrically connecting structure includes a conductive layer formed on the wall of the thru hole, and the conductive layer connects the conductive structure and the soldering structure.

In another embodiment of the present invention, the electrically connecting structure includes a plurality of conductive layers, and the conductive layer is formed on at least one wall of the grooves.

In another embodiment of the present invention, the flexible substrate includes an accommodating recess formed on the first surface, the conductive structure is disposed in the accommodating recess and the conductive layer is flush with the first surface.

In another embodiment of the present invention, the conductive structure is a metal bump disposed on the first surface.

In another embodiment of the present invention, the soldering structure is a metal bump disposed on the second surface.

In another embodiment of the present invention, the conductive structure is a conductive node disposed on the first surface.

The electrically conducting structure of the flexible substrate circuit board of the present invention, with the grooves formed on one side of the flexible substrate or/and the thru holes form on the flexible substrate, and with the electrically connecting structure formed in the grooves or/and in the thru holes to connect the circuit layer and the soldering structure formed on the two different sides of the flexible substrate.

### BRIEF DESCRIPTION OF THE DRAWINGS

The invention can be more fully understood by reading the subsequent detailed description and examples with references made to the accompanying drawings, wherein:

FIG. 1 is a perspective view of the first embodiment of the electrically conductive structure of the flexible substrate of the present invention.

FIG. 2 is a perspective view from another angle of the embodiment of the FIG. 1 of the electrically conductive structure of the flexible substrate of the present invention.

FIG. 3 is a sectional view of the embodiment of the FIG. 1 along A-A line.

FIG. 4 is a sectional view of the second embodiment of the electrically conductive structure of the flexible substrate of the present invention.

FIG. 5 is a sectional view of the third embodiment of the electrically conductive structure of the flexible substrate of the present invention.

FIG. 6 is a sectional view of the forth embodiment of the electrically conductive structure of the flexible substrate of the present invention.

FIG. 7 is a sectional view of the fifth embodiment of the electrically conductive structure of the flexible substrate of the present invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

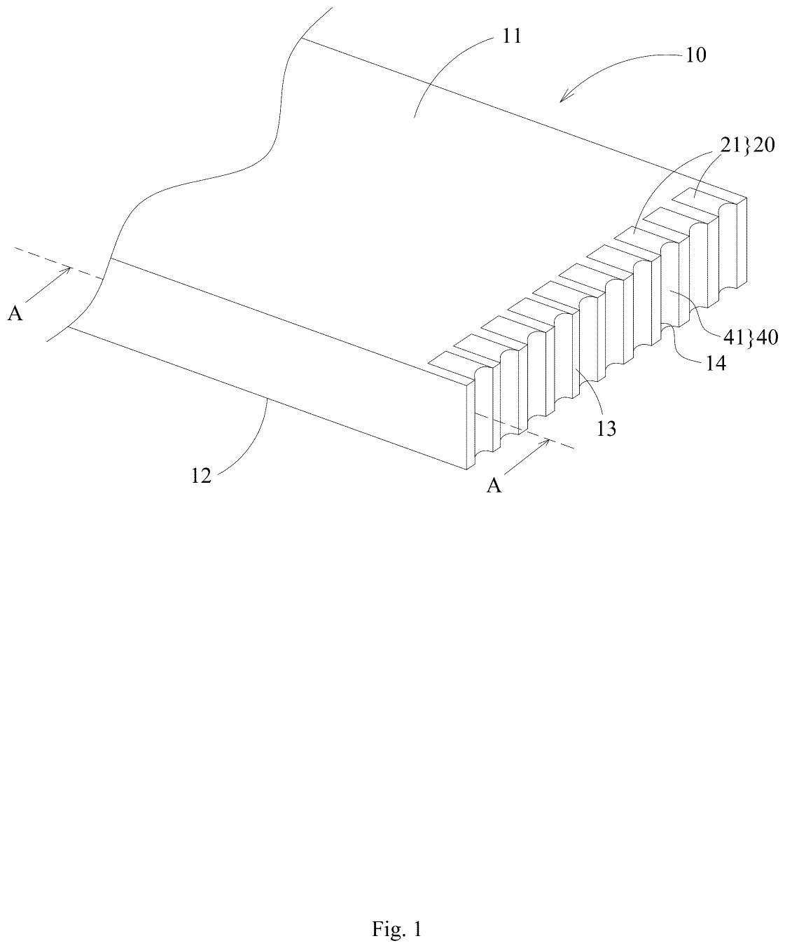

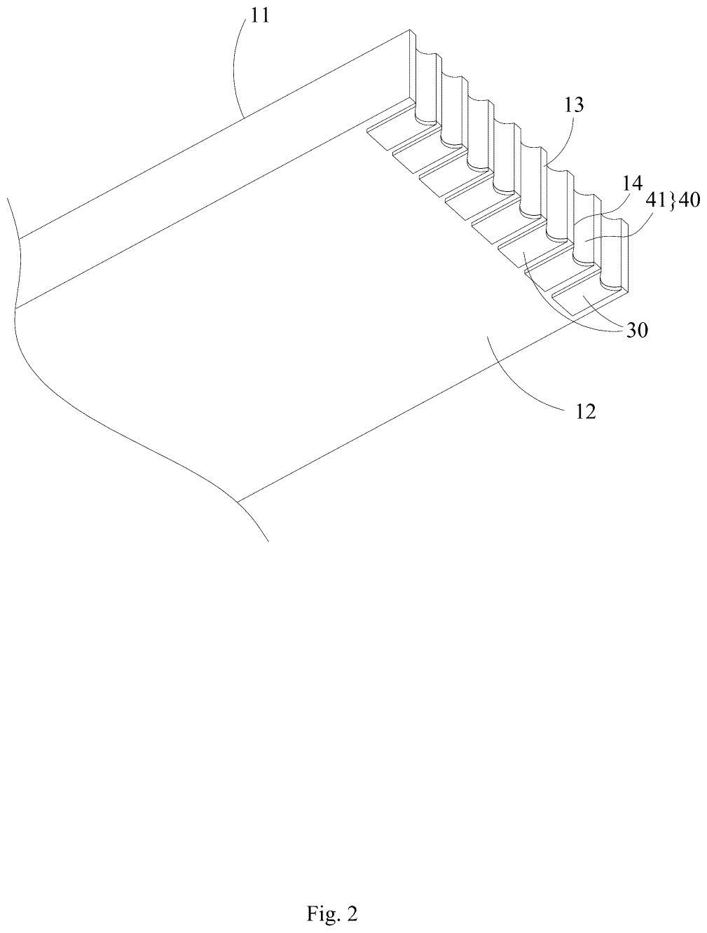

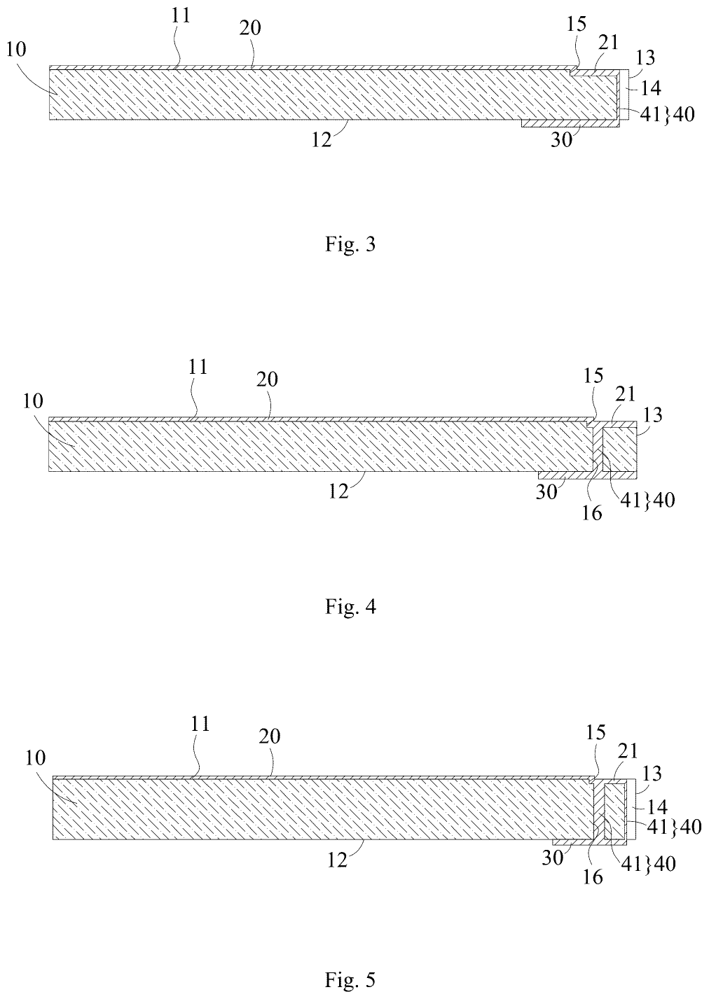

Please refer to FIGS. 1 to 3, they show the perspective view of the first embodiment of the electrically conductive structure of the flexible substrate of the present invention. The electrically conducting structure for a flexible circuit board of this embodiment includes a flexible substrate 10, a circuit layer 20, at least one soldering structure 30 and an electrically connecting structure 40. The flexible substrate 10 includes a first surface 11, a second surface 12, a lateral surface 13 and a plurality of grooves 14. The first surface 11 is opposite to the second surface 12, and the lateral surface 13 connects the first surface 11 and the second surface 12. The grooves 14 are formed on the lateral surface 13 and connect the first surface 11 and the second surface 12. The groove wall of the groove 14 is formed in an arc shape. The process to form the groove 14 could be to first drill a plurality of circular holes on the flexible substrate 10, and then cut the flexible substrate 10 along a straight line passing through the center of the circular hole, that is, forming a half-hole shaped groove 14, commonly known as Stamp hole.

The circuit layer 20 is formed on the first surface 11 and forms an electrically conducting structure 21 located near the lateral surface 13 of the flexible substrate 10. The flexible substrate 10 of this embodiment includes a plurality of accommodating recess 15 formed on the first surface 11. The accommodating recess 15 of this embodiment is in rectangle shape and connected to the groove 14. The conductive structure 21 is disposed in the accommodating recess 15 and is flush with the first surface 11. In other embodiment, the conductive structure 21 could be a metal bump formed on the first surface 11.

The soldering structure 30 is formed on the second surface 12. In this embodiment, the soldering structure 30 is a metal bump formed on the second surface 12 and is connected to the groove 14.

The electrically connecting structure 40 connects conductive structure 21 and the soldering structure 30, in this embodiment, the electrically connecting structure 40 includes a conductive layer 41 formed on the wall of the groove 14 and extending form the first surface 11 to the second surface 12, the conductive layer 41 connects the electrically conducting structure 21 and the soldering structure 30, so the electrically conducting structure 21 and the soldering structure 30 are connected electrically.

In this embodiment, the circuit layer 20, the soldering structure 30 and electrically connecting structure 40 are made by plating and formed on the flexible substrate 10. The material used to make the circuit layer 20, the soldering structure 30 and electrically connecting structure 40 could be copper.

Please refer to FIG. 4, which shows the second embodiment of the present invention. In this embodiment, the flexible substrate 10 includes thru hole 16, and the conductive layer 41 of the electrically connecting structure 40 is formed on the wall of the thru hole 16 and connects the conductive structure 21 and the soldering structure 30, so, the conductive structure 21 and the soldering structure 30 are connected electrically. In this embodiment, the circuit layer 20, the soldering structure 30 and electrically connecting structure 40 are made by plating and formed on the flexible substrate 10. The material used to make the circuit layer 20, the soldering structure 30 and electrically connecting structure 40 could be copper.

Please refer to FIG. 5, which shows the third embodiment of the present invention. In this embodiment, the flexible substrate 10 not only includes the groove 14 formed on the lateral surface 13, but also could include the thru hole 16. The conductive layer 41 of the flexible substrate 10 is formed on the wall of the groove 14 and the wall of the thru hole 16, and the conductive layer 41 connects the conductive structure 21 and the soldering structure 30 so that the conductive structure 21 and the soldering structure 30 are connected electrically. In this embodiment, the circuit layer 20, the soldering structure 30 and electrically connecting structure 40 are made by plating and formed on the flexible substrate 10. The material used to make the circuit layer 20, the soldering structure 30 and electrically connecting structure 40 could be copper.

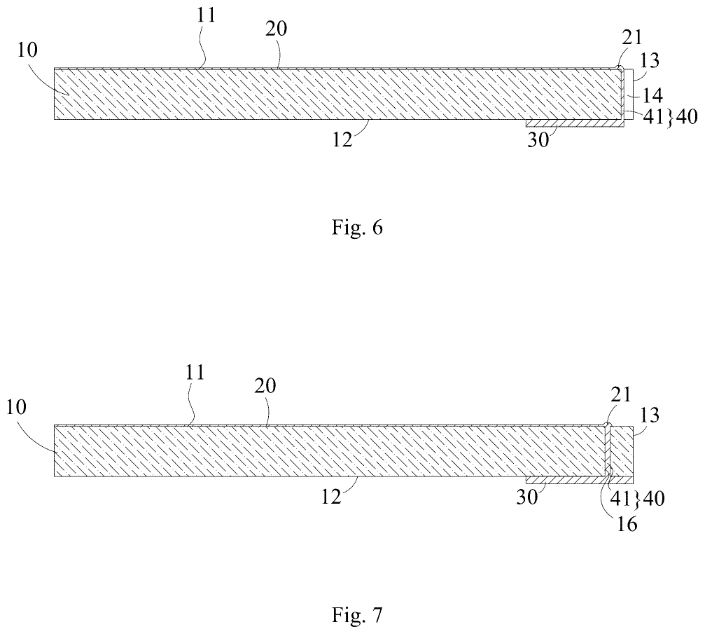

Please refer to FIG. 6, which shows the forth embodiment of the present invention. In this embodiment, the conductive structure 21 is a conductive node formed on the first surface 11, the conductive layer 41 of electrically connecting structure 40 is formed on the wall of the groove 14 and connects the conductive structure 21 and the soldering structure 30 so that the conductive structure 21 and the soldering structure 30 are connected electrically.

Please refer to FIG. 7, which shows the fifth embodiment of the present invention. In this embodiment, the groove 14 is not formed on the lateral surface 13 of the flexible substrate 10, the flexible substrate 10 has the thru hole 16. the conductive structure 21 is a conductive node formed on the first surface 11, the conductive layer 41 of electrically connecting structure 40 is formed on the wall of the thru hole 16 and connects the conductive structure 21 and the soldering structure 30 so that the conductive structure 21 and the soldering structure 30 are connected electrically.

In the present invention, the electrically conducting structure of the flexible substrate circuit board, with the grooves formed on one side of the flexible substrate or/and the thru holes form on the flexible substrate, and with the electrically connecting structure formed in the grooves or/and in the thru holes to connect the circuit layer and the soldering structure formed on the two different sides of the flexible substrate. The electrically connecting structure of the flexible substrate could be made by simple process to achieve the connection between the circuit layer and the soldering structure, complex process like FFC is not necessarily employed in this invention to make a thin designed electron device.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electrically conducting structure for a flexible circuit board, comprising:
an flexible substrate, having a first surface, a second surface, a lateral surface and a plurality of grooves, wherein the first surface is opposite to the second surface, and the lateral surface connects the first surface and the second surface, the grooves are formed on the lateral surface and connect the first surface and the second surface;
a circuit layer, formed on the first surface and comprising at least a conductive structure located near the lateral surface;
at least a soldering structure, formed on the second surface; and
an electrically connecting structure, connecting the conductive structure and the soldering structure and extending form the first surface to the second surface.

2. The electrically conducting structure for a flexible circuit board as claimed in claim 1, wherein the flexible substrate comprising at least one thru hole, the at least thru hole going thru the flexible substrate and connects the first surface and the second surface, the electrically connecting structure is formed on the wall of the at least thru hole and connects the at least conductive structure and the at least soldering structure.

3. The electrically conducting structure for a flexible circuit board as claimed in claim 1, wherein the electrically connecting structure comprises at least one conductive layer and the at least one conductive layer is formed on the wall of at least one groove, and the at least one conductive layer connects the at least one conductive structure and the at least one soldering structure.

4. The electrically conducting structure for a flexible circuit board as claimed in claim 3, wherein the electrically connecting structure comprises a plurality of the conductive layers, and the plurality of the conductive layers are formed on the wall of the at least one groove.

5. The electrically conducting structure for a flexible circuit board as claimed in claim 1, wherein the flexible substrate further comprises at least one accommodating recess, and the at least one accommodating recess is formed is formed on the first surface, the at least one conductive structure is disposed in the at least one accommodating recess, and the at least one conductive structure is flush with the first surface.

6. The electrically conducting structure for a flexible circuit board as claimed in claim 1, wherein the at least one electrically conductive structure is a metal bump disposed on the first surface.

7. The electrically conducting structure for a flexible circuit board as claimed in claim 1, wherein the at least one electrically conductive structure is a metal bump disposed on the second surface.

8. The electrically conducting structure for a flexible circuit board as claimed in claim 1, wherein the at least one electrically conductive structure is a conductive node disposed on the first surface.
